(19) United States
(12) Patent Application Publication
(10) Pub. No.: US 2018/0074419 A1
(43) Pub. Date: Mar. 15, 2018

(54) METHODS OF FORMING PATTERNS USING NANOIMPRINT LITHOGRAPHY

(71) Applicant: SK hynix Inc., Gyeonggi-do (KR)

(72) Inventor: Woo Yung JUNG, Seoul (KR)

(21) Appl. No.: 15/464,674

(22) Filed: Mar. 21, 2017

(30) Foreign Application Priority Data
Sep. 12, 2016 (KR) 10-2016-0117590

(51) Int. Cl. G03F 9/00; G03F 7/00

(52) U.S. Cl. CPC G03F 9/7042; G03F 7/0002

(57) ABSTRACT

A method of forming patterns is provided. The method includes forming a resist layer on a substrate, imprinting transfer patterns of a template on the resist layer, performing an alignment operation to correct a position of the substrate or the template, increasing a viscosity of the resist layer while the alignment operation is performed, and curing the resist layer after the alignment operation terminates.

### CROSS-REFERENCE TO RELATED APPLICATIONS

This U.S. non-provisional patent application claims priority under 35 U.S.C 119(a) to Korean Application No. 10-2016-0117590, filed on Sep. 12, 2016 in the Korean Intellectual Property Office (KIPO), the disclosure of which is incorporated herein by references in its entirety.

### BACKGROUND

### 1. Technical Field

Various embodiments of the present disclosure relate to methods of forming fine patterns and, more particularly, to methods of forming fine patterns using a nanoimprint lithography technique.

### 2. Related Art

In the semiconductor industry, a lot of effort has been focused on developing technologies for transferring fine pattern images onto a wafer in order to realize integrated circuits with a high integration density. A nanoimprint lithography (NIL) technique has been evaluated as an attractive lithography technique which is efficiently usable for fabrication of nanostructures at a low cost. According to a typical NIL technique, a template (a stamp or a mold) in which nanostructures are carved may be put on a resist layer which is spin-coated or dispensed on a semiconductor wafer (a substrate), and the template may be pressed toward the resist layer to transfer the nanostructures into the resist layer. The NIL technique may be typically categorized as either a thermoplastic NIL technique or an ultraviolet NIL (UV-NIL) technique. The thermoplastic NIL technique requires applying heat to the resist layer, whereas the UV-NIL technique requires irradiating a UV-ray onto the resist layer.

When the template having carved nanostructures is pressed toward the resist layer to transfer the pattern shapes of the carved nanostructures into the resist layer, the pattern shapes transferred into the resist layer may be misaligned with patterns formed under the resist layer to cause an overlay error. Although, various methods of suppressing occurrence of the overlay error have been developed further improvements are desirable for producing more reliable, higher density semiconductor devices that require fine patterns.

### SUMMARY

According to an exemplary embodiment, there is provided an improved method of forming fine patterns. The method is advantageous in that it allows forming fine patterns on a resist layer positioned on a substrate with reduced risk of an overlay error.

The method includes forming a resist layer on a substrate, embedding transfer patterns of a template into the resist layer to fill spaces between the transfer patterns with a portion of the resist layer, performing an alignment operation to correct the positions of the transfer patterns in the resist layer, performing a first exposure step to increase a viscosity of the resist layer during the alignment operation, performing a second exposure step to cure the resist layer after the alignment operation terminates, and separating the template from the resist layer.

According to an exemplary embodiment, there is provided a method of forming fine patterns. The method includes forming a resist layer on a substrate, imprinting transfer patterns of a template on the resist layer, performing an alignment operation to correct a position of the substrate or the template, increasing a viscosity of the resist layer while the alignment operation is performed, and curing the resist layer after the alignment operation terminates.

In an exemplary embodiment of the present inventive concept, a method of forming fine patterns may include: providing a substrate including an imprintable medium and a template having a patterned surface; embedding the patterned surface into the imprintable medium; adjusting a position of the patterned surface for a first period having a first start time and a first end time; irradiating a first exposure light having a first intensity onto the imprintable medium for a second period having a second start time and a second end time; irradiating a second exposure light having a second intensity which is higher than the first intensity onto the imprintable medium for a third period having a third start time and a third end time; and separating the patterned surface and the imprintable medium at the third end time of the third period, wherein the second start time of the second period is earlier than the first end time of the first period.

### BRIEF DESCRIPTION OF THE DRAWINGS

Various embodiments of the present disclosure will become more apparent in view of the attached drawings and accompanying detailed description, in which:

FIG. 1 is a schematic illustrating a nanoimprint lithography apparatus used in methods of forming fine patterns, according to exemplary embodiments;

FIG. 2 is a process flowchart illustrating a method of forming fine patterns using a nanoimprint lithography technique, according to an exemplary embodiment;

FIG. 3 illustrates timings of an alignment operation and an exposure operation of FIG. 2;

FIGS. 4 and 5 are graphs illustrating intensity of an exposure light irradiated during the exposure operation of FIG. 2 as a function of time;

FIGS. 6 to 11 are cross-sectional views illustrating a method of forming fine patterns using a nanoimprint lithography technique, according to an exemplary embodiment; and

FIG. 12 is a graph illustrating an attenuation phenomenon of an alignment position error in a nanoimprint lithography technique, according to an exemplary embodiment.

### DETAILED DESCRIPTION OF THE EMBODIMENTS

Exemplary embodiments will be described in more detail with reference to the accompanying drawings. The present disclosure, however, may be embodied in various different forms, and should not be construed as being limited to the illustrated embodiments herein. Rather, these embodiments are provided as examples so that this disclosure will be thorough and complete, and will fully convey the various aspects and features of the present invention to those skilled in the art.

The drawings are not necessarily to scale and, in some instances, proportions may have been exaggerated in order to more clearly illustrate the various elements of the embodiments. For example, in the drawings, the size of elements and the intervals between elements may be exaggerated compared to actual sizes and intervals for convenience of illustration.

The terminology used herein is for the purpose of describing particular embodiments only and is not intended to be limiting of the present invention. As used herein, singular forms are intended to include the plural forms as well, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, the terms used herein may have the same meaning as commonly understood by one of ordinary skill in the art to which the embodiments belong in view of the present disclosure.

It will be understood that although the terms first, second, third etc. may be used herein to describe various elements, these elements should not be limited by these terms. These terms are only used to distinguish one element from another element, but not used to define only the element itself or to mean a particular sequence. Thus, a first element in some embodiments could be termed a second element in other embodiments without departing from the teachings of the inventive concept.

It will also be understood that when an element or layer is referred to as being “on,” “over,” “below,” “under,” or “outside” another element or layer, the element or layer may be in direct contact with the other element or layer, or intervening elements or layers may be present. Other words used to describe the relationship between elements or layers should be interpreted in a like fashion (e.g., “between” versus “directly between” or “adjacent” versus “directly adjacent”).

The following embodiments may be applied to realization of integrated circuits such as dynamic random access memory (DRAM) devices, phase change random access memory (PcRAM) devices or resistive random access memory (ReRAM) devices. Moreover, the following embodiments may be applied to realization of memory devices such as static random access memory (SRAM) devices, flash memory devices, magnetic random access memory (MRAM) devices or ferroelectric random access memory (FeRAM) devices. Furthermore, the following embodiments may be applied to realization of logic devices in which logic circuits are integrated.

Same reference numerals refer to same elements throughout the specification. Even though a reference numeral is not mentioned or described with reference to a drawing, the reference numeral may be mentioned or described with reference to another drawing. In addition, even though a reference numeral is not shown in a drawing, it may be mentioned or described with reference to another drawing.

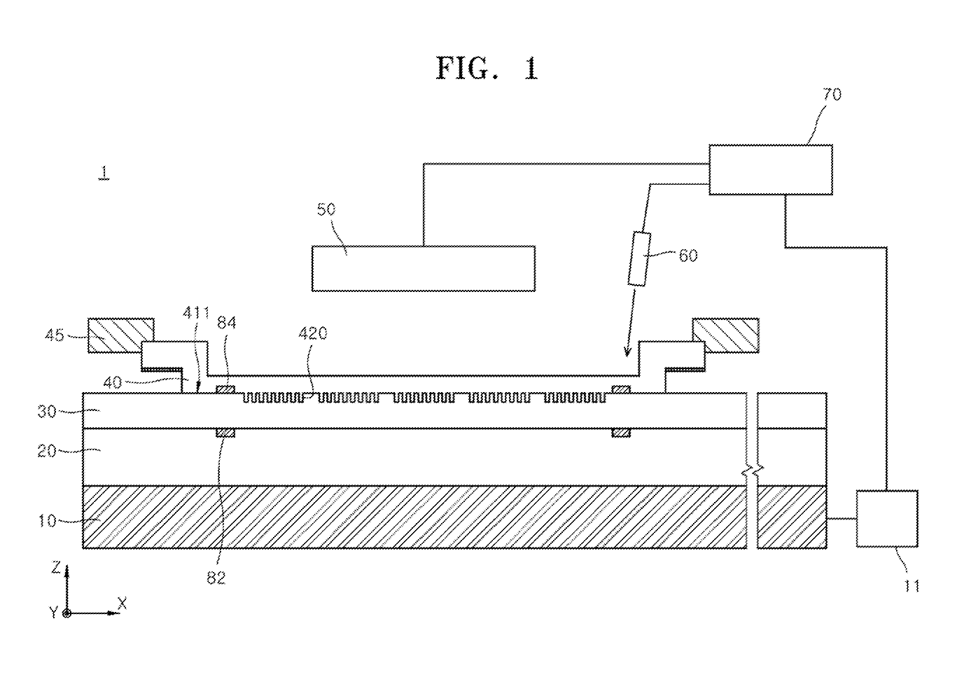

FIG. 1 illustrates a nanoimprint lithography (NIL) apparatus 1 used in methods of forming fine patterns according to exemplary embodiments. Referring to FIG. 1, the NIL apparatus 1 may be configured to use a photo curable imprint technique that irradiates an exposure light onto a resist layer 30 coated on a substrate 20 to cure pattern shapes transferred to the resist layer 30 by the exposure light. The NIL apparatus 1 may be configured to perform an imprint operation to form patterns on the substrate 20. The NIL apparatus 1 may repeatedly perform the imprint operation on the substrate 20 to form the patterns on a plurality of shot regions of the substrate 20.

The NIL apparatus 1 may include a substrate stage 10 that functions as a holder for holding and supporting the substrate 20 on which the patterns are formed. The substrate 20 is loaded on a top surface of the substrate stage 10. The substrate 20 may be a semiconductor wafer, for example, a silicon wafer on which semiconductor devices are formed. The substrate 20 may be a panel-shaped substrate. The substrate stage 10 may be driven to move or rotate together with the substrate 20 in a horizontal direction on an X-Y plane. For example, the substrate stage 10 may move together with the substrate 20 in an X-axis direction or a Y-axis direction on the X-Y plane or may rotate together with the substrate 20 in a clockwise direction or a counterclockwise direction on the X-Y plane. The substrate stage 10 may be coupled to a stage driver 11 in order to drive the substrate stage 10 in a horizontal direction. The stage driver 11 may control the substrate stage 10 to hold the substrate 20 to maintain a horizontal level and move minutely in a horizontal direction.

The resist layer 30 that is positioned on the substrate 20 may act as an imprintable medium for receiving the transfer fine patterns of the template. The resist layer 30 may include a photo curable coating material. For example, the resist layer 30 may be formed of a photo curable resin containing photosensitizers to UV light. The resist layer 30 may be formed by spin-coating an imprintable medium or photo curable material on the substrate 20.

The NIL apparatus 1 may include a template 40 for nanoimprint. The template 40 may be a stamp or a mold which includes transfer patterns 420 constituting a nano-structure to be transferred to the resist layer 30. The transfer patterns 420 may be defined by a patterned surface 411 of the template 40. The patterned surface 411 may be a surface of the template 40 and may face the resist layer 30. The patterned surface 411 may be in contact with the resist layer 30 during the imprint operation. The transfer patterns 420 defined by the patterned surface 411 may be provided to have the same shapes as patterns to be formed in the resist layer 30. The transfer patterns 420 may be fine patterns having a nano-scale size or a nano-scale critical dimension (CD). The nano-scale size or the nano-scale CD may correspond to a range of a few nanometers to several tens of nanometers.

The NIL apparatus 1 may include a template holder 45 for holding and guiding the template 40 to and from the imprint position. The template holder 45 may be driven to move the template 40 in a vertical direction Z which is perpendicular to a surface of the substrate 20. In order to perform the imprint operation, the template holder 45 may bring the template into contact with the resist layer 30 so that the transfer patterns 420 are inserted into the resist layer 30. For example, the template holder 45 may hold the template 40 and may move the template down so that the patterned surface 411 of the template 40 comes into contact with the resist layer 30. Subsequently, the template holder 45 may apply an effective pressure to the template 40 so that the transfer patterns 420 of the template 40 are inserted into the resist layer 30. After the resist layer 30 is fully cured, the template holder 45 may move upwardly so that the template 40 is separated from the resist layer 30.

The NIL apparatus 1 may include an illuminator 50 that irradiates an exposure light onto the resist layer 30. The illuminator 50 may be configured to irradiate first and second exposure lights onto the resist layer 30 to partially cure and fully cure the resist layer 30. More specifically, as initiating the imprinting step, after the template is being pressed against the resist layer, the illuminator 50 may first emit the first exposure light to partially cure the resist layer 30 so that it may have the right viscosity to hold the imprinted transfer patterns 420. The first exposure light may be applied in the middle of a period in which the imprinted fine pattern is formed on the resist layer. During this period the alignment process may also be performed to substantially eliminate any overlay error. Once the alignment have been terminated then the resist layer 30 may be fully cured by irradiating the second exposure light onto the resist layer 30. By fully curing the resist layer 30 the shapes of the imprinted patterns in the resist layer 30 are preserved without any deformation even after the template 40 is detached from the resist layer 30 which is fully cured.

Hence, the first exposure light is designed to be irradiated onto the resist layer 30, so that a viscosity of the resist material of the resist layer 30 may increase gradually so that the resist material of the resist layer 30 may have a sticky state but not completely cured to allow minute position adjustments to reduce overlay errors. The fluidity of the resist material can be reduced and be restricted by the sticky state of the resist material then the overlay error due to the vibration of the NIL apparatus 1 may be reduced. The first exposure light may be a light which is different from the second exposure light. In an embodiment, the intensity of the first exposure light may be different from the intensity of the second exposure light. The first and second exposure lights may be UV light. However, other lights may be employed without departing from the scope of the present invention.

When the first exposure light is irradiated onto the resist layer 30, the resist layer 30 may not be fully cured but partially cured. To partially cure the resist layer 30 means a semi-cure or a soft-cure so that the resist material of the resist layer 30 is cured to still have sufficient fluidity to allow for the alignment operation to take place and for the fine patterns to be transferred on the resist layer. As the resist material of the resist layer 30 is partially cured, a viscosity of the resist material of the resist layer 30 may increase. Accordingly, the fluidity of the resist layer 30 partially cured may be reduced as compared with the initial resist layer 30. The resist layer 30 fully cured by the second exposure light may have no fluidity so that deformation of the resist layer 30 fully cured is not allowed. In contrast, the resist layer 30 partially cured by the first exposure light may still have the fluidity thereof so that the resist layer 30 which is partially cured may be deformed.

The illuminator 50 may include a light source generating an ultraviolet (UV) light as an exposure light. The UV light generated by the light source of the illuminator 50 may be irradiated onto the resist layer 30 through the template 40 that is in contact with the resist layer 30 to perform the imprint operation. In order that the resist layer 30 sequentially has a deformable, partially cured status and a non-deformable, fully cured status, the illuminator 50 may be configured to sequentially irradiate the two different UV lights having different intensities onto the resist layer 30. For example, the illuminator 50 may operate to irradiate the first exposure light having a first intensity and the second exposure light having a second intensity higher than the first intensity after the irradiation of the first exposure light. The transition from the first UV light to the second UV light may be a sharp, step-wise transition, or may be a soft, gradual transition. In an embodiment, the illuminator 50 may be configured to gradually change the intensity of the exposure light irradiated onto the resist layer 30. For example, the illuminator 50 may be configured to irradiate the first exposure UV light having the first intensity onto the resist layer 30 and to gradually increase the first intensity of the first exposure UV light to provide the second exposure UV light having the second intensity higher than the first intensity. As such, the illuminator 50 may be configured to include illumination means capable of varying the intensity of the exposure light as may be needed.

The NIL apparatus 1 may perform an alignment operation for correcting positions of the transfer patterns 420 of the template 40 so that the transfer patterns 420 are located at predetermined positions on the resist layer 30. First alignment keys 82 may be disposed on the substrate 20 to act as alignment reference marks for the alignment operation. Second alignment keys 84 may be disposed on the template 40 to respectively correspond to the first alignment keys 82. The NIL apparatus 1 may include an alignment detector 60 for detecting the relative positions of the first and second alignment keys 82 and 84 and any misalignment between them. The alignment detector 60, based on the relative position of the first and second alignment keys 82 and 84, may measure an offset value between the template 40 and the substrate 20 to calculate an overlay error, i.e., an alignment position error. The alignment detector 60 may be configured to include a detection light illumination system that irradiates a light toward the first and second alignment keys 82 and 84 and a light receiving system that receives images or interference patterns of the first and second alignment keys 82 and 84. The alignment detector 60 may detect relative position differences or overlap differences between the first alignment keys 82 and the second alignment keys 84 to extract parameters employed in the calculation of the overlay error (also referred to as an alignment error).

The NIL apparatus 1 may include a controller 70 that controls the imprint operation, the alignment operation including the overlay error detection operation, and operations of the illuminator 50. The controller 70 may control an operation of the template holder 45 so that the template 40 performs the imprint operation with the resist layer 30. The controller 70 may control an operation of the alignment detector 60 to measure an overlay error value between the template 40 and the substrate 20 on which the resist layer 30 is formed. In addition, the controller 70 may control the stage driver 11 using information on the measured overlay value to move the substrate stage 10 supporting the substrate 20 so that an alignment error between the template 40 and the substrate 20 is corrected by readjusting a position of the substrate 20. The controller 70 may control an operation of the illuminator 50 to irradiate the first exposure light onto the resist layer 30 while the alignment operation is performed. The controller 70 may also control the operation of the illuminator 50 to irradiate the second exposure light onto the resist layer 30 after the alignment operation is performed. The controller 70 may upwardly move the template holder 45 so that the template 40 is detached from the resist layer 30 after the resist layer 30 is cured by the second exposure light.

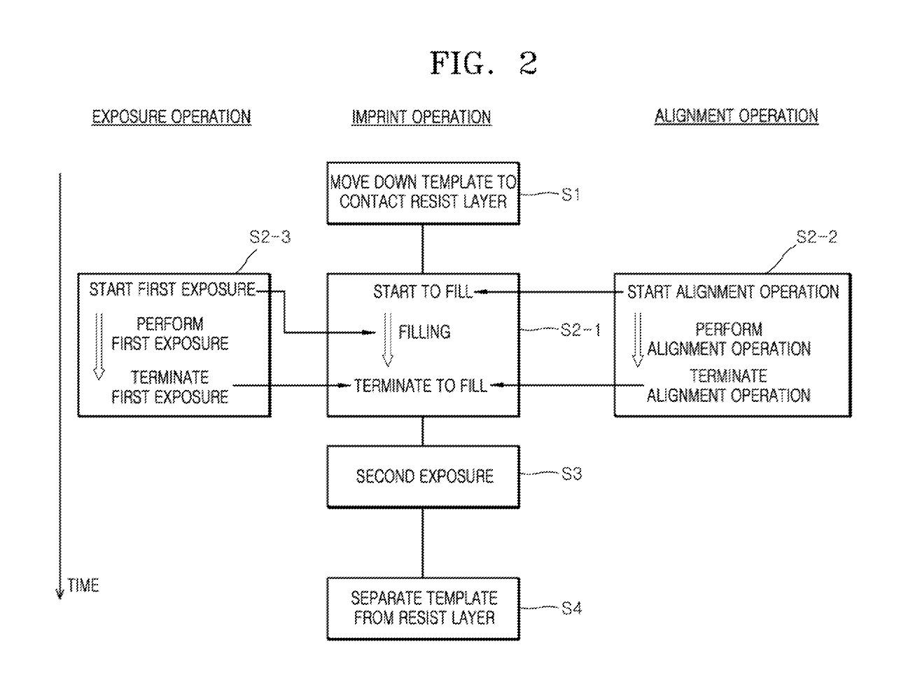

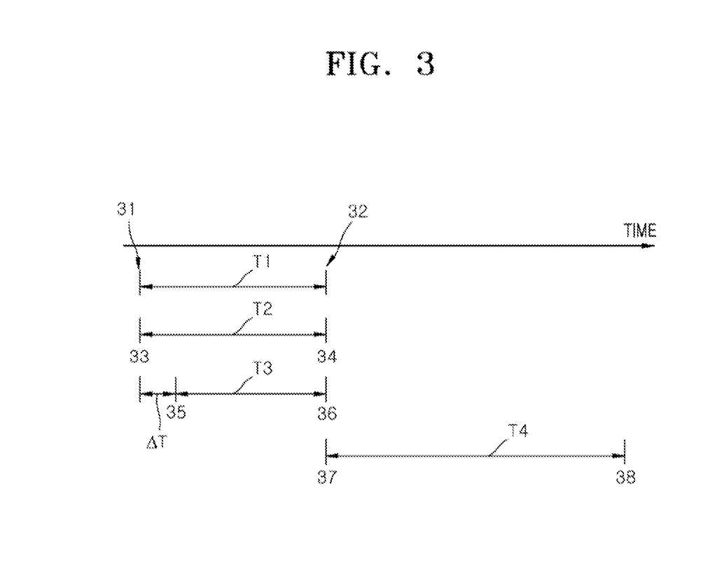

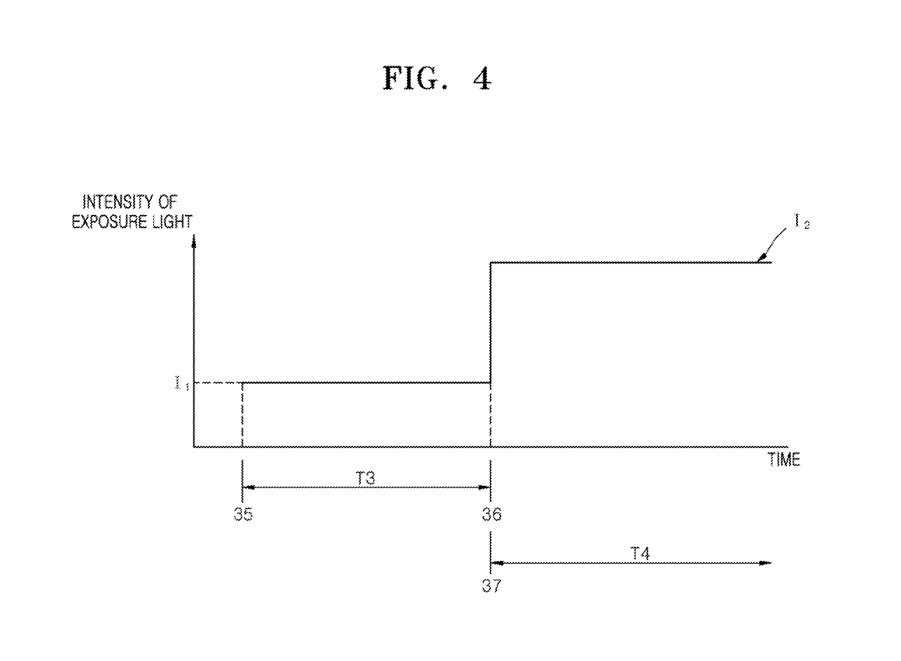

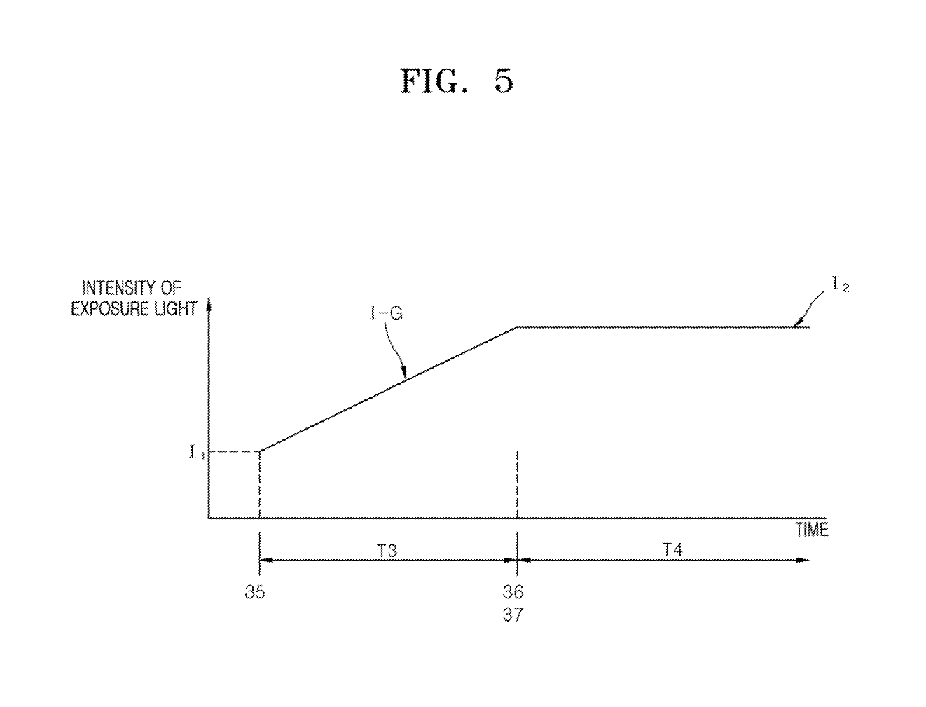

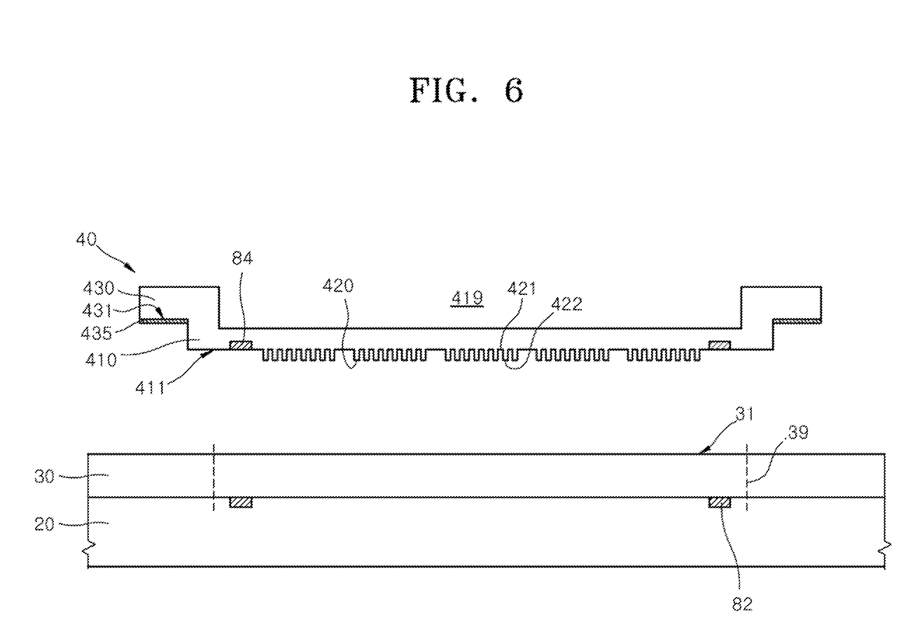

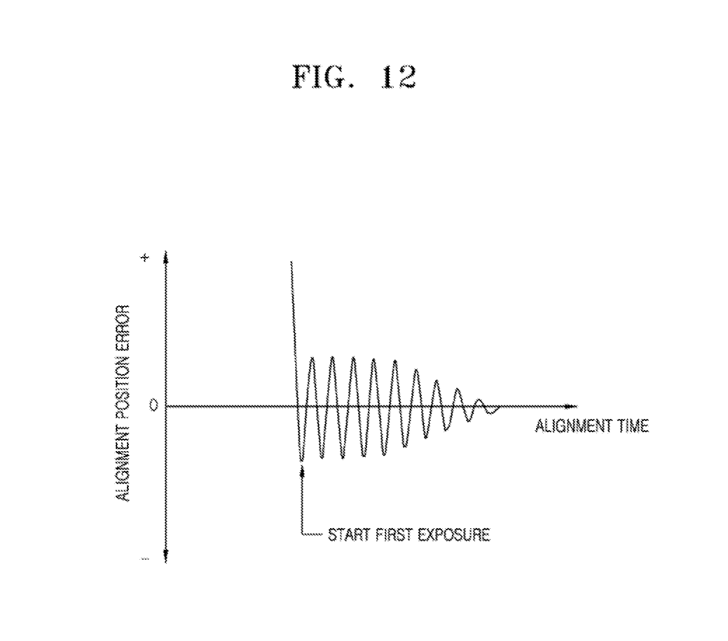

FIG. 2 is a process flowchart illustrating a method of forming fine patterns using an NIL technique according to an exemplary embodiment, and FIGS. 6 to 11 are cross-sectional views illustrating a method of forming fine patterns using an NIL technique according to an exemplary embodiment. FIG. 3 illustrates timings of an alignment operation and an exposure operation of FIG. 2, and FIGS. 4 and 5 are graphs illustrating intensity of an exposure light irradiated during the exposure operation of FIG. 2 as a function of a time. FIG. 12 is a graph illustrating an attenuation phenomenon of an alignment position error in an NIL technique according to an exemplary embodiment.

Referring to FIGS. 2 and 6, the method of forming fine patterns on a resist layer 30 which is placed on top of a semiconductor substrate 20 according to an exemplary embodiment may include using a photo curable imprint technique. The method may include an imprint operation for transferring the fine patterns from a template 40 to the resist layer 30 (see steps S1, S2-1, S3 and S4 of FIG. 2), an alignment operation (see a step S2-2 of FIG. 2) for reducing or preventing an alignment error between the substrate 20 and the template 40 to ensure that the fine patterns are transferred to a desired position in the resist layer 30, and an exposure operation including a first exposure step (see a step S2-3 of FIG. 2) for partially curing or increasing a viscosity of the resist layer 30 and a second exposure step (see the step S3 of FIG. 2) for substantially fully curing the resist layer 30. Various steps of the imprint operation for transferring the fine patterns of the template form the template onto the resist layer 30 may be sequentially performed as the time elapses. While the imprint operation is performed, the first exposure step S2-3 and the second exposure step S3 may be performed and the alignment operation S2-2 may also be performed. The precise timings of these operations will be explained with reference to FIG. 3.

More specifically, the substrate 20 may be loaded onto the substrate stage 10 of the NIL apparatus 1, and the template 40 may be aligned with a shot region 39 of the resist layer 30 (See FIGS. 1 and 6). The substrate 20 may be a wafer. The resist layer 30 may be formed by spin-coating a resist material on the substrate 20, however, the invention is not limited in this way. Any other suitable method for forming or placing the resist layer 30 on the substrate 20 may be employed. The substrate 20 on which the resist layer 30 is formed may be loaded onto the substrate stage 10, and the template 40 may be disposed on the resist layer 30 so that the transfer patterns 420 of the template 40 face a surface 31 of the resist layer 30. In an exemplary embodiment of the present inventive concept, the patterned surface 411 of the template 40 may include a plurality of transfer patterns 420 having a plurality of recessed portions 421 and protrusions 422. The shape of the transfer patterns may vary by design.

The template 40 may have a mesa shaped member 410 protruding toward the surface 31 of the resist layer 30 and a body member 430 supporting the mesa shaped member 410. In such a case, the patterned surface 411 may be a surface of the mesa shaped member 410 to face the surface 31 of the resist layer 30. The body member 430 of the template 40 may have a recessed backside surface which is opposite to the patterned surface 411. Accordingly, the recessed backside surface of the body member 430 may provide a cavity 419. The mesa shaped member 410 may be easily transformed because of the presence of the cavity 419 defined by the recessed backside surface of the mesa shaped member 410. That is, when the patterned surface 411 of the mesa shaped member 410 is in contact with the resist layer 30 or is detached from the resist layer 30, the patterned surface 411 of the mesa shaped member 410 may easily warp to have a convex shape due to the cavity 419 defined by the backside surface of the mesa shaped member 410.

A light blocking layer 435 may be disposed on a surface 431 of the body member 430, which is adjacent to the mesa shaped member 410, to face the resist layer 30. The light blocking layer 435 may block the light for curing the resist layer 30, for example, an ultraviolet (UV) ray. The mesa shaped member 410 may protrude from the surface 431 of the body member 430. Thus, a level difference may exist between the patterned surface 411 of the mesa shaped member 410 and the surface 431 of the body member 430. The patterned surface 411 of the mesa shaped member 410 may have a rectangular shape in a plan view. An entire region of the patterned surface 411 may correspond to the imprinting shot region 39 defined by a single shot of the NIL process.

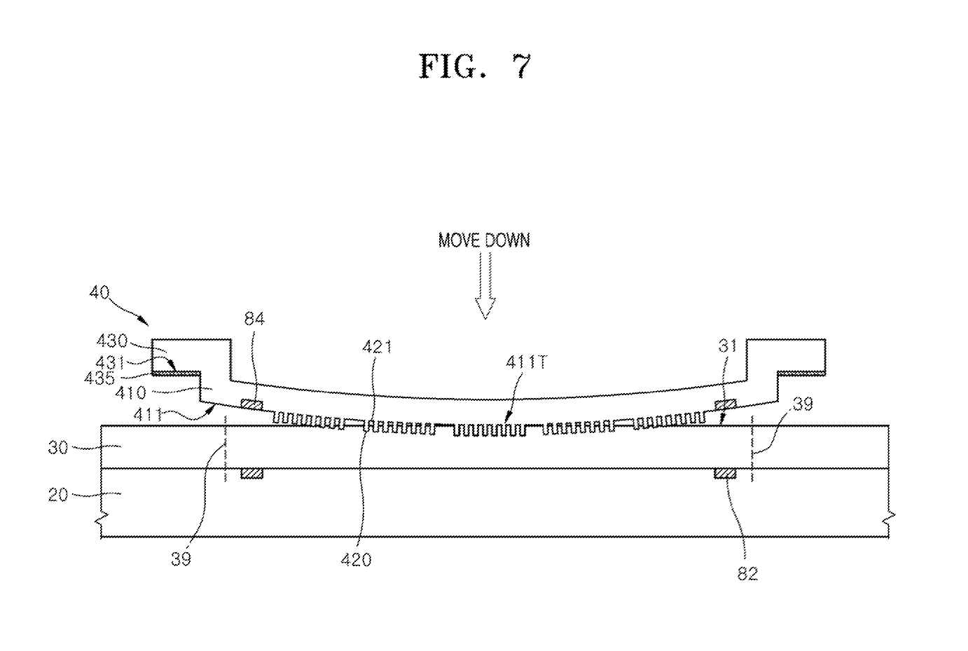

Referring to FIGS. 2 and 7, the controller (70 of FIG. 1) may move down the template holder 45 so that a portion of the template 40 is in contact with the surface 31 of the resist layer 30 (see the step S1 of FIG. 2). The template holder 45 may deform the template 40 so that a central portion 411T of the template 40 convexly protrudes toward the surface 31 of the resist layer 30 and may move downwardly so that the deformed template 40 moves toward the surface 31 of the resist layer 30.

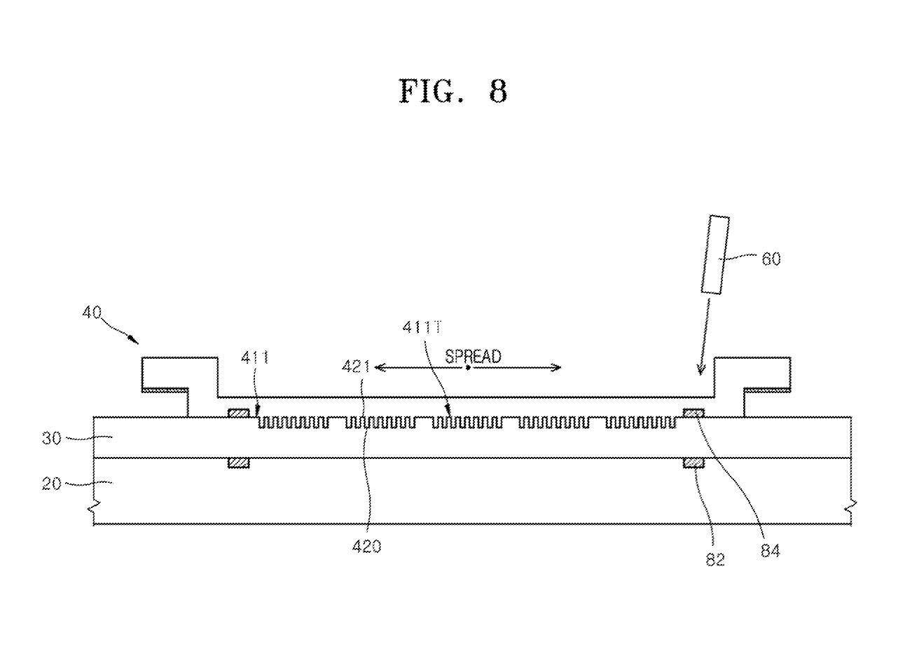

Referring to FIG. 8, after the central portion 411T of the template 40 contacts the surface 31 of the resist layer 30, the template 40 may be spread so that an entire portion of the patterned surface 411 of the template 40 is in contact with the surface 31 of the resist layer 30. After the entire portion of the patterned surface 411 of the template 40 is in contact with the surface 31 of the resist layer 30, the template 40 may be pressed down to embed the transfer patterns 420 of the template 400 into the resist layer 30. If the template 40 is pressed down, recessed portions 421 between the transfer patterns 420 may be filled with a resist material of the resist layer 30. While the recessed portions 421 are filled with the resist layer 30 (see the step S2-1 of FIG. 2), the alignment operation may be performed (see the step S2-2 of FIG. 2).

While the recessed portions 421 are filled with the resist layer 30, the alignment operation may be performed to measure positions of the transfer patterns 420 and to put the transfer patterns 420 at predetermined positions (see the step S2-2 of FIG. 2). After a step of filling the recessed portions 421 with the resist layer 30 starts, the alignment detector 60 may irradiate a light toward the first alignment keys 82 providing a reference position of the substrate 20 and the second alignment keys 84 providing a reference position of the template 40 and may receive images or interference patterns of the first and second alignment keys 82 and 84 to detect an alignment error between the substrate 20 and the template 40. If the alignment error between the substrate 20 and the template 40 occurs, the substrate 20 may move to compensate for the alignment error. As illustrated in FIG. 3, a time period T1 for the step of filling the recessed portions 421 with the resist layer 30 (see also the step S2-1 of FIG. 2) may start at a point of time “31” and may terminate at a point of time “32”. In addition, a time period T2 for the alignment operation (see also the step S2-2 of FIG. 2) may start at a point of time “33” corresponding to substantially the same point of time as the point of time “31” and may terminate at a point of time “34” corresponding to substantially the same point of time as the point of time “32”. That is, a time period “T2” that the alignment operation (see the step S2-2 of FIG. 2) is performed may substantially overlap with a time period “T1” that the step of filling the recessed portions 421 with the resist layer 30 (see the step S2-1 of FIG. 2) is performed.

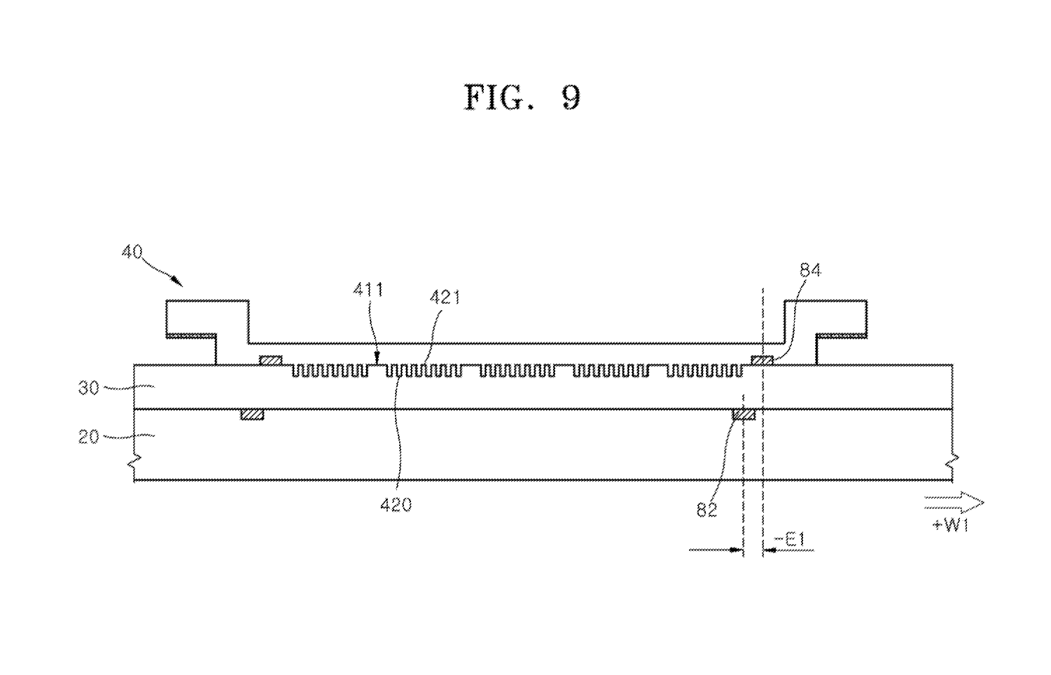

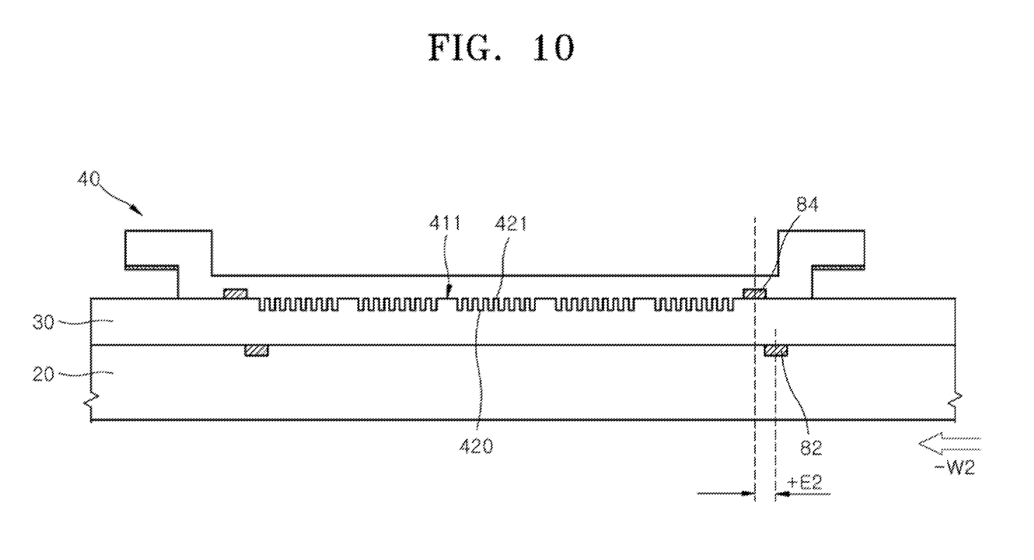

Referring to FIG. 9, if an alignment error corresponding to a value of negative E1 (−E1) between the template 40 and the substrate 20 is detected, the substrate 20 may be moved by a distance “+W1” in an opposite direction to a direction that the first alignment keys 82 are horizontally shifted with respect to the second alignment keys 84 to perform a first alignment operation for compensating for the alignment error. Referring to FIG. 10, if an additional alignment error corresponding to a value of positive E2 (+E2) between the template 40 and the substrate 20 is detected after the first alignment operation, the substrate 20 may be moved by a distance to perform a second alignment operation for compensating for the additional alignment error. Sub-alignment steps such as the first and second alignment operations may be repeatedly performed until the second alignment keys 84 are accurately aligned with the first alignment keys 82. As a result, the template 40 may be aligned with the substrate 20 within an allowable range “E0” of the alignment error.

If the alignment error between the template 40 and the substrate 20 is within the allowable range “E0”, both of the alignment operation (the step S2-2 of FIG. 2) and the step of filling the recessed portions 421 with the resist layer 30 (the step S2-1 of FIG. 2) may terminate. Subsequently, the controller (70 of FIG. 1) may control an operation of the illuminator (50 of FIG. 1) to perform a second exposure step (see the step S3 of FIG. 2) for curing the resist layer 30 on the substrate 20 which is accurately aligned with the template 40.

Referring to FIGS. 2 and 8, while the alignment operation is performed, movement of the substrate 20 or the template 40 may be accompanied by vibration. The resist layer 30 disposed between the substrate 20 and the template 40 may have a relatively low viscosity to exhibit a relatively high fluidity. Thus, the resist layer 30 may function as a lubricant between the substrate 20 and the template 40. Accordingly, the substrate 20 or the template 40 may easily move by weak mechanical vibration to degrade the alignment accuracy between the substrate 20 and the template 40.

The movement of the substrate 20 or the template 40 due to the fluidity of the resist layer 30 may disturb the alignment operation. In spite of the alignment operation, the substrate 20 or the template 40 may be undesirably slipped even by the weak vibration to cause an alignment error which is due to the fluidity of the resist layer 30. A thickness of the resist layer 30 may be reduced to suppress the movement of the substrate 20 or the template 40 due to the fluidity of the resist layer 30.

If the thickness of the resist layer 30 is reduced, the resist layer 30 may be locally and rapidly crystallized at regions that the template 40 and the resist layer 30 are in contact with each other. The local and rapid crystallization of the resist layer 30 may disturb the local movement of the substrate 20 or the template 40 during the alignment operation which is performed to compensate for the alignment error. Thus, a pattern position distortion, for example, a field distortion may occur to cause failure of correction of the alignment error.

If the thickness of the resist layer 30 increases, the field distortion may be effectively suppressed. However, if the thickness of the resist layer 30 increases, the fluidity of the resist layer 30 may also increase. Thus, the substrate 20 or the template 40 may be undesirably slipped even by the weak vibration. As a result, it may be difficult to accurately perform the alignment operation.

While the alignment operations (corresponding to the step S2-2 of FIG. 2) illustrated in FIGS. 9 and 10 are performed, a step of increasing a viscosity of the resist layer 30 may be additionally performed to lower the fluidity of the resist layer 30. For example, the controller (70 of FIG. 1) may control the illuminator 50 so that the illuminator 50 irradiates a first exposure light onto the resist layer 30. The resist layer 30 may be partially cured by the first exposure light to gradually increase the viscosity of the resist layer 30. That is, the first exposure step performed with the first exposure light may increase the viscosity of the resist layer 30 so that the resist layer 30 may become stickler. Accordingly, the viscosity of the resist layer 30 treated by the first exposure step may be higher than an initial viscosity of the resist layer 30 before the first exposure step is performed. That is, the fluidity of the resist layer 30 treated by the first exposure step may be lower than an initial fluidity of the resist layer 30 before the first exposure step is performed.

As illustrated in FIGS. 2 and 3, a time period T3 for the first exposure step S2-3 may start at a point of time “35” after the point of time “33” that the alignment operation S2-2 starts. That is, the first exposure step S2-3 may start while the alignment operation S2-2 is performed. In addition, the first exposure step S2-3 may terminate at a point of time “36” corresponding to substantially the same point of time as the point of time “34”. That is, the first exposure step S2-3 and the alignment operation S2-2 may terminate at the same time. The time period T3 for the first exposure step S2-3 may start after a certain time interval ΔT passes from the point of time “33” that the alignment operation S2-2 starts. The first exposure step S2-3 may start at a point time (i.e., the point of time “35”) that the alignment error is reduced to be within a desired range while the alignment operation S2-2 is performed. For example, the first exposure step S2-3 may start after a first sub-alignment step among a plurality of sub-alignment steps constituting the alignment operation is performed to measure the alignment error and the substrate 20 moves to compensate for the alignment error, while the step of filling the recessed portions 421 with the resist layer 30 (the step S2-1 of FIG. 2) is performed.

It may be effective to reduce a time period “T3” that the first exposure step S2-3 is performed. The certain time interval ΔT between the point of time “33” and the point of time “35” may be set to be 10% to 40% of the time period “T2” that the alignment operation S2-2 is performed. In exemplary embodiments, the certain time interval ΔT between the point of time “33” and the point of time “35” may be set to be 20% to 30% of the time period “T2” that the alignment operation S2-2 is performed. After the first exposure step S2-3 is performed during the time period “T3”, the time period T4 for the second exposure step S3 may start at a point of time “37” to cure the resist layer 30 and may terminate at a point of time “38” that a time period “T4” elapses from the point of time “37”.

Referring to FIG. 2, the first exposure step S2-3 may be performed to increase the viscosity of the resist layer 30 and to reduce the fluidity of the resist layer 30.

Thus, a process condition of the first exposure step S2-3 may be different from a process condition of the second exposure step S3 which is performed after the alignment operation S2-2 terminates. As illustrated in FIG. 4, the first exposure step S2-3 may be performed so that the illuminator (50 of FIG. 1) irradiates a first exposure light having a first intensity I₁ onto the resist layer 30. The second exposure step S3 may be performed to fully cure the resist layer 30 so that shapes of transferred patterns in the resist layer 30 are not deformed any more. Thus, the second exposure step S3 may be performed so that the illuminator (50 of FIG. 1) irradiates a second exposure light having a second intensity I₂ greater than the first intensity I₁ onto the resist layer 30. The second intensity I₂ may be several tens of times the first intensity I₁. For example, the first intensity I₁ may be equal to or less than one fiftieth the second intensity 12. In exemplary embodiments, the second intensity I₂ may be equal to or greater than fifty times the first intensity I₁ and may be equal to or less than one hundred times the first intensity I₁.

As illustrated in FIG. 4, the controller (70 of FIG. 1) of the NIL apparatus (1 of FIG. 1) may control an operation of the illuminator (50 of FIG. 1) so that the first exposure light having the first intensity I₁ is irradiated toward the template 40 during the time period “T3” and so that the second exposure light having the second intensity I₂ is irradiated toward the template 40 during the time period “T4”.

Referring to FIG. 5, the controller (70 of FIG. 1) of the NIL apparatus (1 of FIG. 1) may control an operation of the illuminator (50 of FIG. 1) so that the intensity of the first exposure light gradually increases during a first exposure period “I-G”. The exposure light may have the first intensity I₁ at the point of time “35” that the first exposure step S2-3 starts, and the intensity of the exposure light may gradually increase during the time period “T3” that the first exposure step S2-3 is performed and may reach the second intensity I₂ at the point of time “36” that the first exposure step S2-3 terminates.

Referring again to FIG. 2, while the alignment operation S2-2 is performed, the first exposure step S2-3 may be performed to lower the fluidity of the resist layer 30. Since the fluidity of the resist layer 30 is lowered, an overlay error (i.e., an alignment position error) caused by movement of the substrate 20 or the template 40 due to vibration may be reduced to substantially converge on zero, as illustrated in FIG. 12. As the fluidity of the resist layer 30 is reduced during the first exposure step S2-3, the alignment position error due to the vibration may also be reduced. Thus, the alignment operation S2-2 may be effectively performed to suppress the occurrence of the alignment error. As illustrated in FIG. 12, the first exposure step S2-3 may start at a point of time that the alignment error is firstly compensated to be within a predetermined range.

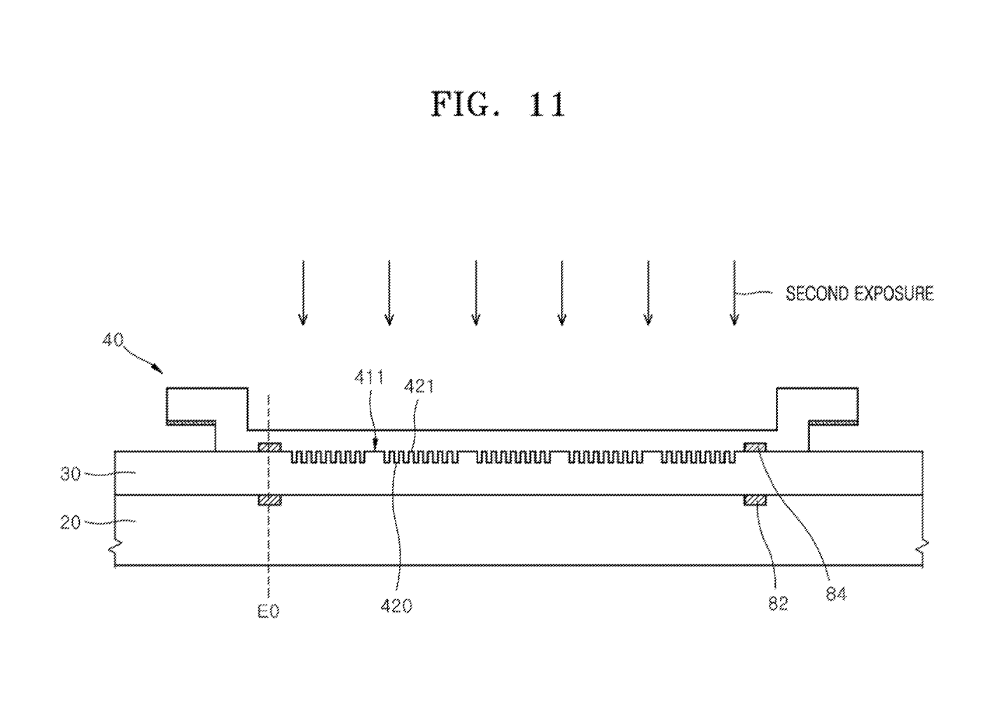

Referring again to FIG. 11, after the alignment operation is performed to obtain the allowable alignment error range of “E0”, the second exposure step S3 may be performed to cure the resist layer 30. Subsequently, the template 40 may be detached and separated from the resist layer 30 to terminate an imprint lithography process (see a step S4 of FIG. 2).

According to the present disclosure, the alignment operation S2-2 and the first exposure step S2-3 may be performed during the imprint operation to lower the fluidity of the resist layer 30. Thus, undesirable movement of the substrate 20 or the template 40 may be suppressed to reduce the alignment error due to the vibration. Accordingly, the transfer patterns 420 may be accurately transferred into the resist layer 30 by the alignment operation S2-2. Since the undesirable movement of the substrate 20 or the template 40 is suppressed by reducing the fluidity of the resist layer 30, it may be possible to increase a thickness of the resist layer 30 if the first exposure step S2-3 is performed. In such a case, the local crystallization and the field distortion of the resist layer 30 may be suppressed.

According to the exemplary embodiments described above, nano-scale structures or nano structures can be fabricated on a large-sized substrate. The nano structures may be used in fabrication of polarizing plates or in formation of reflective lens of reflective liquid crystal display (LCD) units. The nano structures may also be used in fabrication of separate polarizing plates as well as in formation of polarizing parts including display panels. For example, the nano structures may be used in fabrication of array substrates including thin film transistors or in processes for directly forming the polarizing parts on color filter substrates. Further, the nano structures may be used in molding processes for fabricating nanowire transistors or memories, molding processes for fabricating electronic/electric components such as nano-scaled interconnections, molding process for fabricating catalysts of solar cells and fuel cells, molding process for fabricating etch masks and organic light emitting diodes (OLEDs), and molding process for fabricating gas sensors.

The methods according to the aforementioned embodiments and structures formed thereby may be used in fabrication of integrated circuit (IC) chips. The IC chips may be supplied to users in a raw wafer form, in a bare die form or in a package form. The IC chips may also be supplied in a single chip package form or in a multi-chip package form. The IC chips may be integrated in intermediate products such as mother boards or end products to constitute signal processing devices. The end products may include toys, low end application products, or high end application products such as computers. For example, the end products may include display units, keyboards, or central processing units (CPUs).

The exemplary embodiments of the present disclosure have been disclosed for illustrative purposes. Those skilled in the art will appreciate that various modifications, additions and substitutions are possible, without departing from the scope and spirit of the present disclosure and the accompanying claims

What is claimed is:

1. A method of forming a pattern, the method comprising:
forming a resist layer on a substrate;
embedding transfer patterns of a template into the resist layer to fill spaces between the transfer patterns with a portion of the resist layer;
performing an alignment operation to correct the position of the transfer patterns in the resist layer;
performing a first exposure step to increase a viscosity of the resist layer during the alignment operation;
performing a second exposure step to cure the resist layer after the alignment operation terminates; and
separating the template from the resist layer.

2. The method of claim 1, wherein a first exposure light used in the first exposure step is different from a second exposure light used in the second exposure step.

3. The method of claim 1, wherein a first exposure light used in the first exposure step is an ultraviolet (UV) ray having an intensity which is lower than an intensity of a second exposure light used in the second exposure step.

4. The method of claim 1,
wherein the second exposure step is performed using a second exposure light having a second intensity; and
wherein the first exposure step starts using a first exposure light having a first intensity which is lower than the second intensity,
wherein an intensity of the first exposure light gradually increases from the first intensity to the second intensity during the first exposure step.

5. The method of claim 1,
wherein the first exposure step starts after a point of time that the alignment operation starts; and
wherein the first exposure step starts while the alignment operation is performed.

6. The method of claim 1, wherein the first exposure step and the alignment operation terminate at the same time.

7. The method of claim 1, wherein the alignment operation includes:
measuring positions of a first alignment key disposed on the substrate and a second alignment key disposed on the template to extract an alignment error;
moving the substrate to correct the alignment error; and
repeatedly executing measuring the positions of the first and second alignment keys to extract the alignment error and moving the substrate to correct the alignment error.

8. The method of claim 1, wherein the resist layer is formed by spin-coating a resist material on the substrate.

9. A method of forming patterns, the method comprising:
forming a resist layer on a substrate;
imprinting transfer patterns of a template on the resist layer;
performing an alignment operation to correct a position of the substrate or the template;
increasing a viscosity of the resist layer while the alignment operation is performed; and
curing the resist layer after the alignment operation terminates.

10. The method of claim 9, wherein increasing the viscosity of the resist layer includes a first exposure step that irradiates an ultraviolet (UV) ray onto the resist layer.

11. The method of claim 10, wherein curing the resist layer includes a second exposure step that irradiates a UV ray onto the resist layer.

12. The method of claim 11, wherein an intensity of the UV ray used in the first exposure step is lower than an intensity of the UV ray used in the second exposure step.

13. The method of claim 9, wherein the resist layer is formed by spin-coating a resist material on the substrate.

14. A method of forming patterns, the method comprising:
providing a substrate including an imprintable medium and a template having a patterned surface;
embedding the patterned surface into the imprintable medium;
adjusting a position of the patterned surface for a first period having a first start time and a first end time;
irradiating a first exposure light having a first intensity onto the imprintable medium for a second period having a second start time and a second end time;
irradiating a second exposure light having a second intensity which is higher than the first intensity onto the imprintable medium for a third period having a third start time and a third end time; and
separating the patterned surface and the imprintable medium at the third end time of the third period,
wherein the second start time of the second period is earlier than the first end time of the first period.

15. The method of claim 14, wherein the third start time of the third period is later than the first end time of the first period and the second end time of the second period.

16. The method of claim 14, wherein the first intensity of the first exposure light gradually increases to the second intensity during the second period.
